(19) United States
(12) Patent Application Publication
(10) Pub. No.: US 2012/0152298 A1
(43) Pub. Date: Jun. 21, 2012

(54) RACK MOUNTED THERMOELECTRIC GENERATOR ASSEMBLIES FOR PASSIVELY GENERATING ELECTRICITY WITHIN A DATA CENTER

(75) Inventors: Daniel de Souza Casali, Valinhos (BR); Rodrigo Ceron Ferreira de Castro, Campinas (BR); Breno Henrique Leitao, Campinas (BR); Thiago Cesar Rotta, Campinas (BR)

(73) Assignee: INTERNATIONAL BUSINESS MACHINES CORPORATION, Armonk, NY (US)

(21) Appl. No.: 12/972,007

(22) Filed: Dec. 17, 2010

(51) Int. Cl. H01L 35/30

(52) U.S. Cl. 136/212

(57) ABSTRACT

An apparatus for generating electricity in a computer rack includes a plurality of thermoelectric generator modules secured in a planar assembly having a first side and a second side, wherein each thermoelectric generator module has a first thermally conductive substrate exposed on the first side of the planar assembly and a second thermally conductive substrate exposed on the second side of the planar assembly, and wherein the plurality of thermoelectric generator modules are operatively coupled in a circuit to supply electrical current. The apparatus further comprises a first duct for directing a first fluid stream across the first side of the planar assembly to supply heat to the first thermally conductive substrate, and a second duct for directing a second fluid stream across the second side of the planar assembly to withdraw heat from the second thermally conductive substrate. The planar assembly is secured within a housing between the first and second ducts, wherein the housing has a form factor for being received in a computer rack.

### BACKGROUND

1. Field of the Invention

The present invention relates to a thermoelectric generator assembly for generating electricity from thermal differences within a data center.

2. Background of the Related Art

One of the greatest challenges faced in data centers is how to lower the energy consumption in order to get closer to the ideal green data center. Investments in server virtualization and consolidation, hardware that consumes less energy, air flow studies, better equipment allocation and organization, are techniques widely adopted for a power-optimized green data center. These techniques reduce or optimize a given characteristic, either physical or computational, so that energy savings can be achieved.

In a well-designed data center seeking to be energy-efficient, empty spaces on each rack must be filled with panels to maintain hot and cold sides to get better use of air flow through the rack for equipment cooling purposes, thus saving energy by reducing the amount of power needed to operate the cooling systems, including the computer room air conditioning (CRAC).

### BRIEF SUMMARY

One embodiment of the present invention provides an apparatus for generating electricity in a computer rack. The apparatus comprises a plurality of thermoelectric generator modules secured in a planar assembly having a first side and a second side, wherein each thermoelectric generator module has a first thermally conductive substrate exposed on the first side of the planar assembly and a second thermally conductive substrate exposed on the second side of the planar assembly, and wherein the plurality of thermoelectric generator modules are operatively coupled in a circuit to supply electrical current from the planar assembly. The apparatus further comprises a first duct for directing a first fluid stream across the first side of the planar assembly to supply heat to the first thermally conductive substrate, and a second duct for directing a second fluid stream across the second side of the planar assembly to withdraw heat from the second thermally conductive substrate. The planar assembly is secured within a housing between the first and second ducts, wherein the housing has a form factor for being received in a computer rack.

Another embodiment of the invention provides another apparatus for generating electricity in a computer rack. The apparatus comprises a stack of planar thermoelectric generator assemblies secured in a housing in a spaced apart relationship, wherein the housing has a form factor for being received in a computer rack. The apparatus further comprise a cold air duct on a first side of each thermoelectric generator assembly for directing cold air across the first side of each thermoelectric generator assembly, and a hot air duct on a second side of each thermoelectric generator assembly for directing hot air across the second side of each thermoelectric generator assembly.

### BRIEF DESCRIPTION OF THE SEVERAL VIEWS OF THE DRAWINGS

FIG. 1 is a schematic diagram of a thermoelectric device for generating voltage from a temperature differential.

FIG. 2 is a diagram of a thermoelectric generator module in the form of a thin plaque.

FIG. 3 is a side view of the thermoelectric generator module of FIG. 2.

FIG. 4A is a plan view of a planar thermoelectric generator assembly including an array of the thermoelectric generator modules of FIGS. 2 and 3.

FIG. 4B is an end view of the thermoelectric generator assembly of FIG. 4A.

FIG. 5 is a perspective assembly view of three thermoelectric generator assemblies with associated air flow directing barriers.

FIG. 6 is a front (cold aisle) perspective view of a housing the thermoelectric generator assemblies of FIG. 5.

FIG. 7 is a rear (hot aisle) perspective view of the housing in FIG. 6.

FIG. 8 is a diagram of a miniature fan assembly coupled across the inlet and outlet of one of the air ducts.

### DETAILED DESCRIPTION

One embodiment of the present invention provides an apparatus for generating electricity in a computer rack. The apparatus comprises a plurality of thermoelectric generator modules secured in a planar assembly having a first side and a second side, wherein each thermoelectric generator has a first thermally conductive substrate exposed on the first side of the planar assembly and a second thermally conductive substrate exposed on the second side of the planar assembly, and wherein the plurality of thermoelectric generator modules are operatively coupled in a circuit to supply electrical current from the planar assembly. The apparatus further comprises a first duct for directing a first fluid stream across the first side of the planar assembly to supply heat to the first thermally conductive substrate, and a second duct for directing a second fluid stream across the second side of the planar assembly to withdraw heat from the second thermally conductive substrate. The planar assembly is secured within a housing between the first and second ducts, wherein the housing has a form factor for being received in a computer rack.

The construction of an individual thermoelectric generator module will be generally understood in the art and may be made using various materials and manners of construction. However, a preferred thermoelectric generator module is a solid state device based upon semiconductor p-n junctions. Bismuth telluride (Bi₂Te₃) and gallium arsenide (GaAs) are just two examples of semiconductor materials that are suitable for use in the construction of the thermoelectric generator modules. Embodiments of the invention dispose such semi-conductor materials to both hot and cold, therefore creating a thermal difference across the semi-conductor so that, by means of the Seebeck effect, some amount of electricity is generated. The Seebeck effect is the occurrence of a net source electromotive force (EMF), the absolute Seebeck EMF, between pairs of points in any individual electrically conducting material due to a difference of temperature between them. The existence of this voltage difference causes a continuous current in the conductors when they are configured in the form of a closed loop. A voltage of many micro-volts per degree Kelvin of temperature difference is created in the conducting material.

In a specific example, a commercially available thermoelectric module having dimensions of 4 cm (W)×4 cm (L)×3.3 mm (t) with specifications of maximum current (Imax) of 8.6 amperes, and maximum voltage (Vmax) of 24.6 volts will consume a maximum power (Qmax) of 131 W to create a temperature differential (DT) of 69 degrees Celsius. Such thermoelectric module, when used the other way around as a thermoelectric generator, thus making use of the Seebeck effect, will generate around 1.31 W of power, already accounting for performance losses, when submitted to a temperature difference of 10 degrees Celsius. Given that the difference in the air temperature between hot and cold aisles in a data center is generally around 10 degrees Celsius, such a thermoelectric module can be used as the thermoelectric generator module 20 of this disclosure and may be expected to produce about 1.31W.

The first and second ducts may be formed as part of the housing, formed as part of the planar assembly, or merely positioned within the housing on opposing sides of the planar assembly. Furthermore, the housing may provide support for the planar assembly and the ducts and maintain the proper orientation and spacing of the same. Furthermore, the housing may provide significant portions of the ducts that direct fluid streams across the sides of the planar assembly. For example, the housing provides side walls that center the planar assembly within the housing and establishes ducts of the appropriate dimensions. In one embodiment the first and second ducts may have the same dimensions, such as the same width and height.

In another embodiment, the first fluid stream is a first air stream and the second fluid stream is a second air stream. In order to generate electricity, the first and second air streams must be at different temperatures. For example, the first fluid stream may be a cold air stream contacting a first side of the thermoelectric generator modules to withdraw heat (i.e., heat rejection), and the second fluid stream may be a hot air stream contacting a second side of the thermoelectric generator modules to provide heat (i.e., heat absorption). The hot and cold air may be obtained from the hot and cold aisles available in a data center.

In a further embodiment, the first duct has an inlet through a first end of the housing and the second duct has an inlet through a second end of the housing. Preferably, the first end of the housing is disposed along a first face of the computer rack and the second end of the housing is disposed along a second face of the computer rack. Even more preferably, the computer rack is disposed in a data center with the first face of the computer rack disposed along a hot aisle and the second face of the computer rack disposed along a cold aisle. Optionally, the first duct may also have its outlet through the first end of the housing and the second duct may have its outlet through the second end of the housing.

Embodiments of the apparatus may further include a first air moving device in fluid communication with the first duct for forcing the first air stream through the first duct, and/or a second air moving device in fluid communication with the second duct for forcing the second air stream through the second duct. The air moving device(s) are preferably dedicated to moving air through a designated duct. The air moving device may be, without limitation, a fan or an electrostatic device having an ion emitter electrode disposed a spaced distance upstream in an airflow direction from a collector electrode.

The apparatus may have a form factor that allows the housing to fit in a 1U bay of the computer rack. Although the apparatus might also have a form factor that fits in a 2U by or an even larger bay, a 1U form factor allows the apparatus to be used anywhere in a rack that might otherwise require a filler or dummy chassis.

In a further embodiment of the invention, the plurality of thermoelectric generator modules in the planar assembly are operatively coupled in a series circuit. Alternatively, the plurality of thermoelectric generator modules may be divided into a plurality of groups of thermoelectric generator modules, wherein each group of thermoelectric generator modules are operatively coupled in a series circuit.

Another embodiment of the invention provides another apparatus for generating electricity in a computer rack. The apparatus comprises a stack of a plurality of planar thermoelectric generator assemblies secured in a housing in a spaced apart relationship, wherein the housing has a form factor for being received in a computer rack. The apparatus further comprise a cold air duct on a first side of each thermoelectric generator assembly for directing cold air across the first side of each thermoelectric generator assembly, and a hot air duct on a second side of each thermoelectric generator assembly for directing hot air across the second side of each thermoelectric generator assembly.

In another embodiment, each planar thermoelectric generator assembly includes a plurality of thermoelectric generator modules secured in a planar assembly having a first side and a second side, wherein each thermoelectric generator module has a first thermally conductive substrate exposed on the first side of the planar assembly and a second thermally conductive substrate exposed on the second side of the planar assembly. The plurality of thermoelectric generator modules are operatively coupled in a circuit to supply electrical current from the planar assembly. The plurality of planar thermoelectric generator assemblies are preferably evenly spaced apart and substantially parallel. It should be recognized that each thermoelectric generator assembly in a stack configuration may be made to include the same features as described herein with reference to a single planar assembly of thermoelectric generator modules.

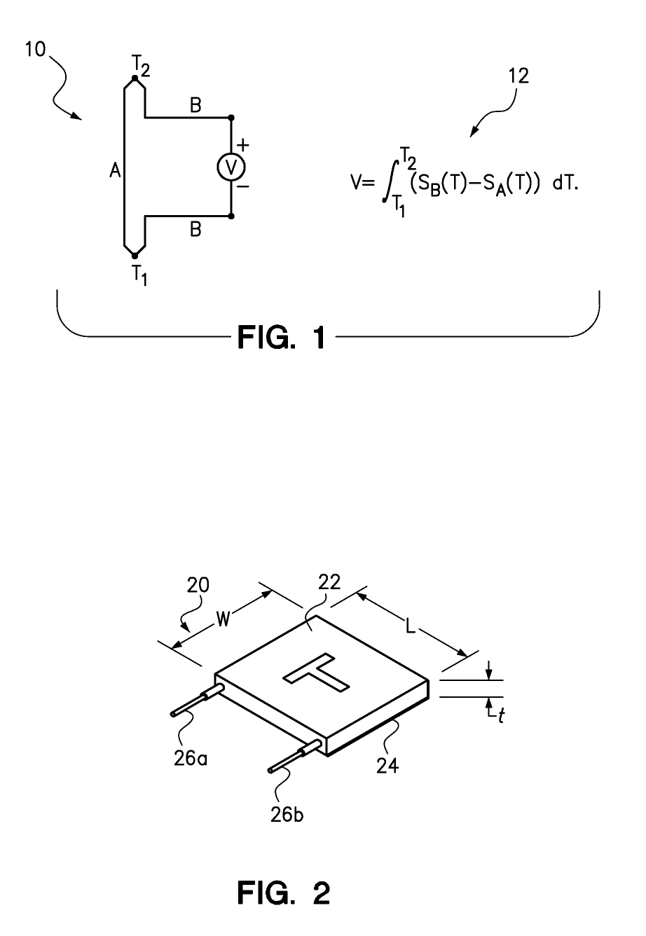

FIG. 1 is a schematic diagram of a thermoelectric device 10 for generating voltage from a temperature differential. The voltage V created by such a circuit configuration can be calculated through the equation 12 set out in FIG. 1, where Sa and Sb are the Seebeck coefficients of two metals A and B as a function of temperature, and T1 and T2 are the temperatures of the two junctions. The Seebeck coefficients are non-linear as a function of temperature, and depend on the conductors' absolute temperature, material, and molecular structure. These coefficients, however, can be approximated linearly where there are no large changes in the temperature differential. It is possible to couple many such circuits in series in order to obtain a stronger voltage since the individual voltage of a single circuit is of the order of micro-volts only. Similarly, many such circuits may be coupled in parallel to obtain greater current. Circuits may also include combinations of thermoelectric generator modules in series and thermoelectric generator modules in parallel in order to provide a desired current and voltage.

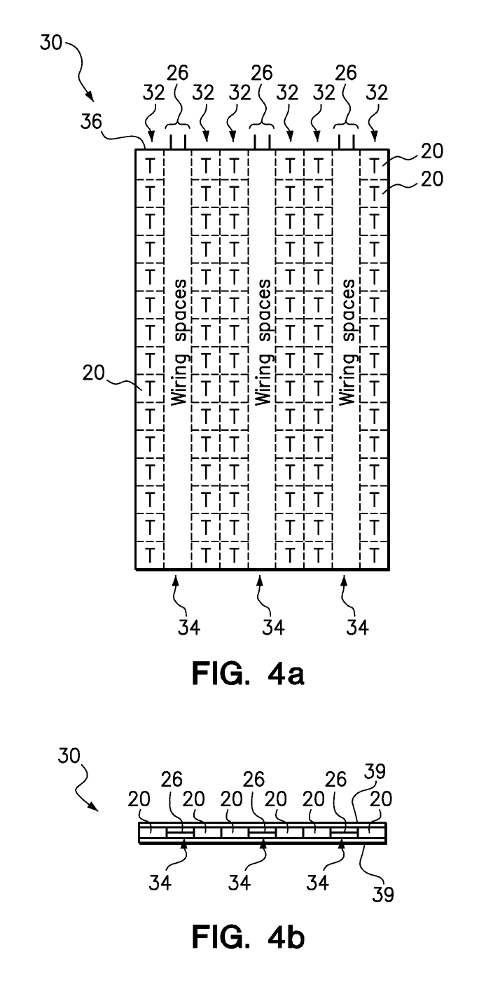

FIG. 2 is a diagram of a thermoelectric generator module 20 in the form of a thin plaque. A single thermoelectric generator module 20 has a top surface 22 having an area of W×L (i.e., width multiplied by length) and a bottom surface 24 having the same amount of surface area. One surface will be placed in contact with a fluid having a first temperature and another surface will be place in contact with a source of hot fluid having a second temperature. The temperature differential between the two sides affects the voltage generated by the plaque. The single thermoelectric generator module 20 also has a thickness t and a pair of wires 26a, 26b for coupling the module 20 into a circuit. Such a circuit may couple multiple thermoelectric generator module in series, in parallel, or some combination of series modules and parallel modules. The module has been illustrated with a bold “T” for reference in conjunction with the thermoelectric generator assembly in FIG. 4.

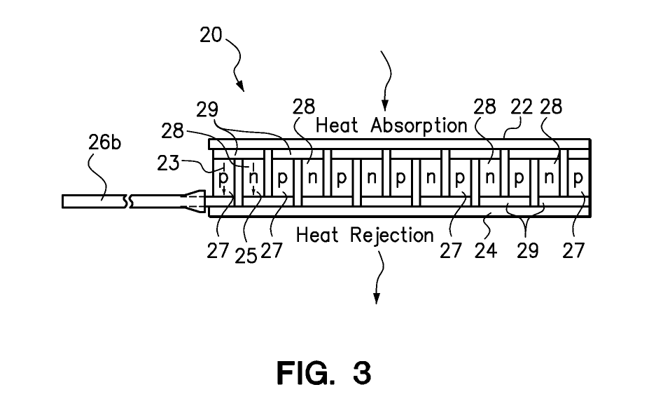

FIG. 3 is a side view of the thermoelectric generator module 20 of FIG. 2. A series of p-type and n-type semiconductor materials are disposed between a top surface substrate 22 and a bottom surface substrate 24. Both substrates 22, 24 are thermally conductive materials, such as a metal. The p-type semiconductor elements 27 and the n-type semiconductor elements 28 are disposed in an alternating pattern. The elements 27, 28 are coupled into a circuit by a plurality of electrically conductive elements 29. Collectively, the semiconductor elements 27, 28 and the conductive elements 29 form a serpentine pattern extending between the top substrate 22 and the bottom substrate. Accordingly, the thermoelectric generator 20 can be described as having a plurality of n-type and p-type semiconductors connected electrically in series and thermally in parallel. In service, heat flows from the top surface 22 (where heat is absorbed from a hot fluid) through the conductive elements and semiconductor elements to the bottom surface 24 (where heat is rejected into a cold fluid). This flow of heat produces electrical power by driving free electrons (e−) in the n-type semiconductor elements 28 in the direction of heat flow (see arrow 25) and holes (h+) in the p-type semiconductor elements 27 in the direction of heat flow (see arrow 23). It should be recognized that the terms “top” and “bottom” are merely references to the drawing in FIG. 3 and that an actual thermoelectric generator module 20 operates independent of its orientation.

FIG. 4A is a plan view of one embodiment of a planar thermoelectric generator assembly 30 including an array of the thermoelectric generator modules or plaques 20 consistent with FIGS. 2 and 3. The thermoelectric generator assembly 30 is suitable for use in a 1U rack space (i.e, a rack space of about 44 cm×71.1 cm×4.3 cm) and includes a planar assembly of 90 thermoelectric generator modules while still having open spaces for wiring. Specifically, the assembly includes 6 rows 32 of modules, where each row has 15 aligned modules. This leaves 3 rows of “open spaces” 34 for interconnecting wiring, wherein each open space is about the width of a plaque itself. However, a thermoelectric generator assembly may be made with other spaces or no spaces.

FIG. 4B is an end view of the thermoelectric generator assembly 30 of FIG. 4A. From this view, it can be seen that the individual thermoelectric generator modules 20 are secured between two rigid thermally conductive members 39, such as metal plates. In the open spaces 34, there is an elongate cavity where the wires 26 from two adjacent rows 32 of generator modules are coupled together. As illustrated here, the generator modules 20 on either side of an open space 34 have their wires 26 coupled in a series circuit with the two ends of the series circuit extending from the end 36 of the assembly 30 in alignment with the open spaces 34. These wires can be further connected in series outside of the 1U rack unit to yield, for example, a single power outlet to which something can be coupled to receive the electricity generated by the assembly.

Using the thermoelectric generator modules of FIGS. 2 and 3, the planar thermoelectric generator assembly 30 may be made having a thickness of 3.3 mm. In even a 1U rack space having a height of 4.3 cm, this leaves available space for one or more additional thermoelectric generator assemblies with an air duct between each of the planes. The orientation of thermoelectric generator assemblies should be alternated (i.e., hot face up, then hot face down, etc.), so that adjacent generator assemblies have either hot surfaces facing each other or cold surfaces facing each other. If the adjacent generator assemblies have hot surfaces facing each other, then there will be a hot air duct there between. If the adjacent generator assemblies have cold surfaces facing each other, then there will be a cold air duct there between. Air ducts on the outer surface of the first and last assembly in a stack will provide air that is appropriate for the hot or cold surface. In such a configuration, the air ducts will typically alternate between a hot duct and a cold duct. While this is an efficient arrangement, other arrangements of generator assemblies and ducts are within the scope of the invention.

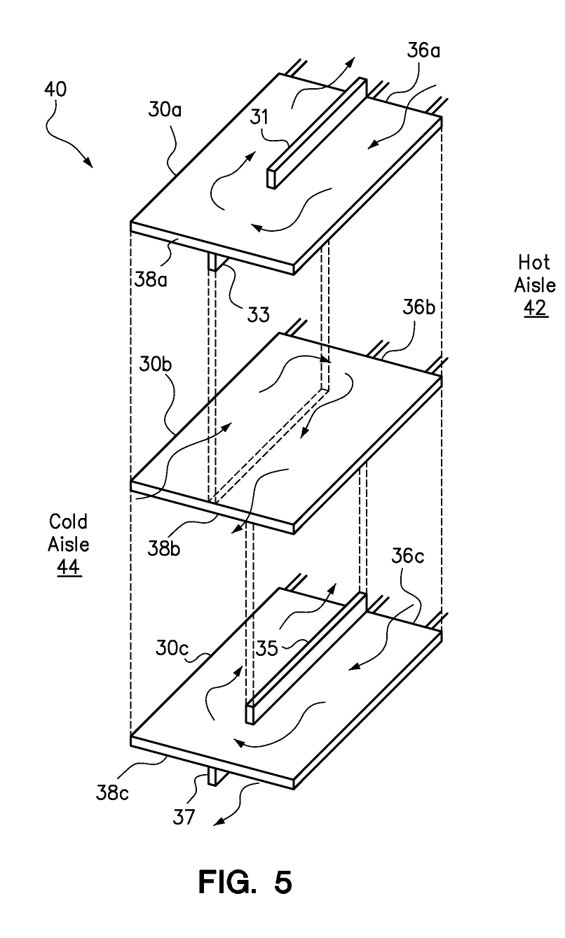

FIG. 5 is a perspective assembly view of a subassembly 40 including three planar thermoelectric generator assemblies 30a-c with airflow directing barriers associated with hot or cold air ducts. A first end 36a-c of each assembly 30a-c is disposed along a hot aisle 42 of a data center and a second end 38a-c of each assembly is disposed along a cold aisle 44 of the data center. The plurality of thermoelectric generator modules (shown in FIG. 4 as elements 20) are not shown, but may be formed across the surfaces of the assemblies 30a-c in accordance with various embodiments.

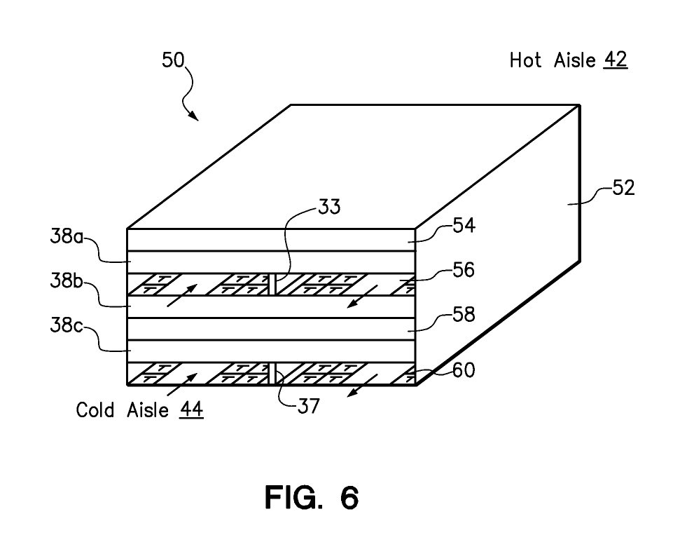

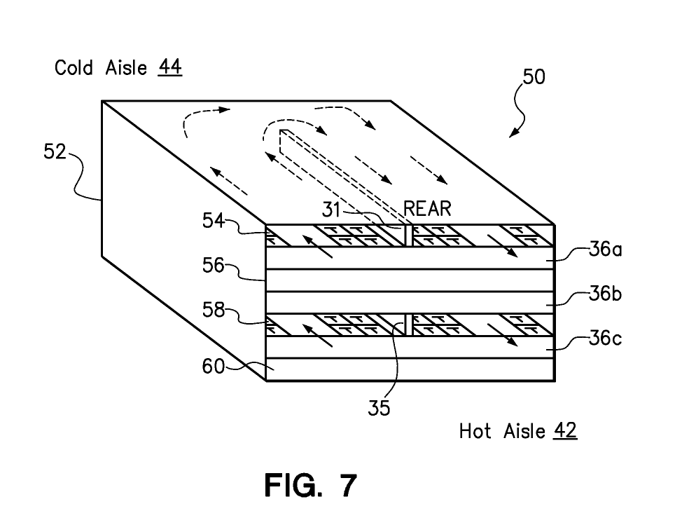

As illustrated with wavy arrows representative of air flow, hot air from the hot aisle 42 flows across the top surface of the upper assembly 30a. The hot air passes around the air flow barrier 31 before returning to the hot aisle 42. A housing (shown in FIGS. 6 and 7) is omitted from FIG. 5 to facilitate illustration of the internal configuration of the ducts, but is using to enclose the top, sides and an end of the duct.

Cold air from the cold aisle 44 flows between the upper assembly 30a and the middle assembly 30b. The cold air passes around the air flow barrier 33 before returning to the cold aisle 44. Because this airflow is between the two assemblies 30a, 30b, this single duct will cool (remove heat from) both the bottom side of the upper thermoelectric generator assembly 30a and the top side of the middle thermoelectric generator assembly 30b.

Hot air from the hot aisle 42 flows between the middle assembly 30b and the lower assembly 30c. The hot air passes around the air flow barrier 35 before returning to the hot aisle 42. Because this airflow is between the two assemblies 30b, 30c, this single duct will provide heat to both the bottom side of the middle thermoelectric generator assembly 30b and the top side of the lower thermoelectric generator assembly 30c.

Cold air from the cold aisle 44 also flows across the bottom side of the lower assembly 30c. The cold air passes around the air flow barrier 37 before returning to the cold aisle 44. For actual use, the three assemblies 30a, 30b, 30c and the four air flow barriers 31, 33, 35, 37 are brought together and positioned in a housing, as shown in reference to FIGS. 6 and 7.

FIG. 6 is a front (cold aisle) perspective view of a 1U thermoelectric generator stack 50 including a housing 52 extending around the subassembly 40 of FIG. 5. The housing 52 encloses the top, bottom, left side, and right side of the subassembly. Furthermore, the housing 52 or other element encloses selected ends of the air ducts. Specifically, the stack 50 may be described as a 7-plane stack having the configuration (from top to bottom): (1) hot air duct 54, (2) thermoelectric generator assembly (see end 38a), (3) cold air duct 56, (4) thermoelectric generator assembly (see end 38b), (5) hot air duct 58, (6) thermoelectric generator assembly (see end 38c), and (7) cold air duct 60. On the front end view shown in FIG. 6, the ends of the two hot air ducts 54, 58 are closed so that the hot air returns back to the hot aisle 42. The arrows illustrate cold air from the cold aisle 44 entering and exiting the stack 50.

FIG. 7 is a back (hot aisle) perspective view of the stack 50 in FIG. 6. Here, the ends of the two cold air ducts 56, 60 are closed so that the cold air returns back to the cold aisle 44. The arrows illustrate hot air from the hot aisle 42 entering and exiting the stack 50. The stack 50 may be secured in a 1U bay of a rack for the purpose of generating electricity from waste heat. The three thermoelectric generator assemblies each have 90 thermoelectric generator modules (per FIG. 4) such that the stack 50 includes 270 modules. Assuming that each thermoelectric generator module generates 1.31 W, the stack would generate as much as 353.7 W. This energy can be used for anything, such as providing electricity to one or more components of the rack or providing data center lighting.

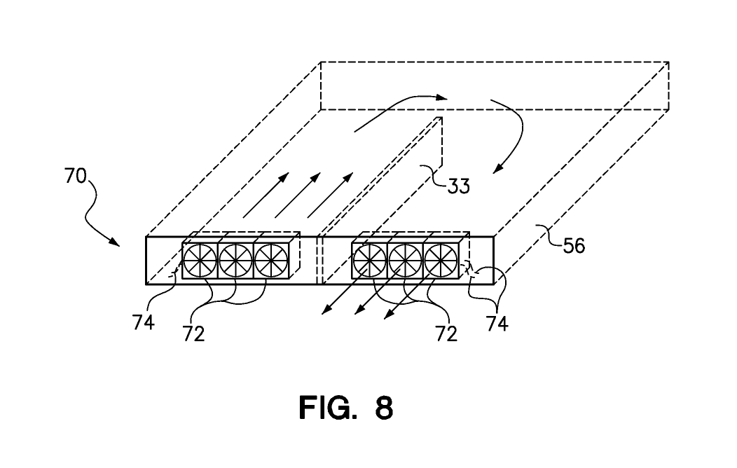

FIG. 8 is a diagram of a miniature fan assembly 70 coupled across the inlet and outlet of one of the air ducts in FIGS. 6 and/or 7. Accordingly, air may be forced through the duct (for example duct 56 of FIG. 6) and across the surface of one or more thermoelectric generator assembly. Preferably, the fans 72 will receive power from the adjacent thermoelectric generator assemblies, such that there is still a net generation of electricity from the stack (for example stack 50 of FIG. 6). For example, the fan wires 74 may be coupled to the output wires of a thermoelectric generator module (see wires 26 of generator module 30 in FIG. 4A). Such air blowers or fans 72 may have a diameter of only several millimeters, such as a 5-millimeter diameter, to fit into the inlet/outlet of the narrow duct. The fans over the inlet (on the left in FIG. 8) will be inwardly directed and the fans over the outlet (on the right in FIG. 8) will be outwardly directed as shown by the arrows. The fans may be secured to the thermoelectric generator assemblies or secured to a portion of the housing, such as with an end cover that is removably secured to the housing after the assemblies are positioned within the housing. Optionally, a larger fan or blower could be used to move air through more than one cold air duct or more than one hot air duct by securing a manifold between the relevant ducts. The foregoing discussion and illustration of fans is provided as a non-limiting example. Other fan types, sizes and arrangements may be implemented within the scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An apparatus for generating electricity in a computer rack, comprising:
a plurality of thermoelectric generator modules secured in a planar assembly having a first side and a second side, wherein each thermoelectric generator module has a first thermally conductive substrate exposed on the first side of the planar assembly and a second thermally conductive substrate exposed on the second side of the planar assembly, and wherein the plurality of thermoelectric generator modules are operatively coupled in a circuit to supply electrical current from the planar assembly;
a first duct for directing a first fluid stream across the first side of the planar assembly to supply heat to the first thermally conductive substrate;
a second duct for directing a second fluid stream across the second side of the planar assembly to withdraw heat from the second thermally conductive substrate; and
a housing securing the planar assembly between the first and second ducts, wherein the housing has a form factor for being received in a computer rack.

2. The apparatus of claim 1, wherein the first fluid stream is a first air stream and the second fluid stream is a second air stream.

3. The apparatus of claim 2, wherein the first duct has an inlet through a first end of the housing and the second duct has an inlet through a second end of the housing.

4. The apparatus of claim 3, wherein the first end of the housing is disposed along a first face of the computer rack and the second end of the housing is disposed along a second face of the computer rack.

5. The apparatus of claim 4, where the computer rack is disposed in a data center with the first face of the computer rack disposed along a hot aisle and the second face of the computer rack disposed along a cold aisle.

6. The apparatus of claim 5, wherein the first duct has an outlet through the first end of the housing and the second duct has an outlet through the second end of the housing.

7. The apparatus of claim 2, further comprising:
a first air moving device in fluid communication with the first duct for forcing the first air stream through the first duct; and
a second air moving device in fluid communication with the second duct for forcing the second air stream through the second duct.

8. The apparatus of claim 1, wherein the housing form factor allows the housing to fit in a 1U bay of the computer rack.

9. The apparatus of claim 1, wherein the plurality of thermoelectric generator modules in the planar assembly are operatively coupled in a series circuit.

10. The apparatus of claim 1, wherein the plurality of thermoelectric generator modules are divided into a plurality of groups of the thermoelectric generator modules, wherein each group of thermoelectric generator modules are operatively coupled in a series circuit.

11. An apparatus for generating electricity in a computer rack, comprising:
a stack of planar thermoelectric generator assemblies secured in a housing in a spaced apart relationship, wherein the housing has a form factor for being received in a computer rack;
a cold air duct on a first side of each thermoelectric generator assembly for directing cold air across the first side of each thermoelectric generator assembly; and
a hot air duct on a second side of each thermoelectric generator assembly for directing hot air across the second side of each thermoelectric generator assembly.

12. The apparatus of claim 11, wherein each planar thermoelectric generator assembly includes a plurality of thermoelectric generator modules secured in a planar assembly having a first side and a second side, wherein each thermoelectric generator module has a first thermally conductive substrate exposed on the first side of the planar assembly and a second thermally conductive substrate exposed on the second side of the planar assembly, and wherein the plurality of thermoelectric generator modules are operatively coupled in a circuit to supply electrical current from the planar assembly.

13. The apparatus of claim 11, wherein the cold air duct communicates with air on a first side of the housing and the hot air duct communicates with air on a second side of the housing.

14. The apparatus of claim 13, wherein the cold air duct has an inlet and an outlet on the first side of the housing, and the hot air duct has an inlet and an outlet on the second side of the housing.

15. The apparatus of claim 11, wherein the housing form factor fills a 1U bay in a computer rack.
